(19) United States
(12) Patent Application Publication
(10) Pub. No.: US 2026/0370971 A1
(43) Pub. Date: Nov. 19, 2026

(54) IMAGING DEVICE AND ELECTRONIC DEVICE

(71) Applicant: SONY SEMICONDUCTOR SOLUTIONS CORPORATION, KANAGAWA (JP)

(72) Inventor: HIROMU KATO, KANAGAWA (JP)

(21) Appl. No.: 19/148,016

(22) PCT Filed: Dec. 1, 2023
(86) PCT No.: PCT/JP2023/043119

§ 371 Date: Jul. 15, 2025

(30) Foreign Application Priority Data
Jan. 27, 2023 (JP) 2023-010650

(51) Int. Cl. H04N 25/709; H03F 3/16; H04N 23/667; H04N 25/77; H04N 25/78

(52) U.S. Cl. CPC H04N 25/709; H04N 23/667; H04N 25/77; H04N 25/78; H03F 3/16

(57) ABSTRACT

To achieve both reduction in power consumption and improvement in image quality of a captured image. An imaging device of the present technology includes: a pixel circuit including a photoelectric conversion unit and an amplification transistor having a gate electrode connected to the photoelectric conversion unit; a first signal line connected to one electrode side of the amplification transistor; a switching unit connected to the first signal line; a second signal line connected to another electrode side of the amplification transistor; a comparator having a comparison input end connected to the second signal line; a selector connected to the first signal line and an output end of the comparator; and a counter connected to an output end of the selector. The switching unit includes a first switch element that selectively connects the first signal line to a power supply node, and a second switch element that selectively connects the first signal line to a current source.

### TECHNICAL FIELD

The present technology relates to an imaging device. Specifically, the present technology relates to an imaging device having a function for reducing power consumption, and an electronic device having the imaging device.

### BACKGROUND ART

In an imaging device such as a complementary metal oxide semiconductor (CMOS) image sensor, for example, a technology for reducing power consumption is known. As such a technology for reducing power consumption, for example, a technology for reducing power consumption by reading a pixel signal by a pulse width modulation (PWM) method has been proposed (see, for example, Patent Document 1).

### CITATION LIST

### Patent Document

Patent Document 1: WO 2007/000879 A

### SUMMARY OF THE INVENTION

### Problems to be Solved by the Invention

As in the above-described conventional technology, power consumption can be reduced by reading the pixel signal by the pulse width modulation method. However, since the above-described conventional technology has a pixel configuration in which the potential VPD of the photodiode is read through the grounded source amplifier, the image quality of the captured image is inferior to that of a pixel configuration in which the pixel signal is read through a source follower circuit (grounded drain circuit) having good frequency characteristics.

The present technology has been made in view of such a situation, and an object thereof is to achieve both reduction in power consumption and improvement in image quality of a captured image.

### Solutions to Problems

The present technology has been made to solve the above-described problems, and a first aspect thereof is an imaging device including: a pixel circuit including a photoelectric conversion unit and an amplification transistor having a gate electrode connected to the photoelectric conversion unit; a first signal line connected to one electrode side of the amplification transistor; a switching unit connected to the first signal line; a second signal line connected to another electrode side of the amplification transistor; a comparator having a comparison input end connected to the second signal line; a selector connected to the first signal line and an output end of the comparator; and a counter connected to an output end of the selector, in which
the switching unit includes a first switch element selectively connecting the first signal line to a power supply node, and a second switch element selectively connecting the first signal line to a current source. This brings about an effect that it is possible to achieve both reduction in power consumption and improvement in image quality of a captured image.

Furthermore, in the first aspect, the switching unit may set a first imaging mode in which image quality of a captured image is relatively high by turning on the first switch element and turning off the second switch element, and set a second imaging mode in which power consumption is relatively low by turning off the first switch element and turning on the second switch element. This brings about an effect that the first imaging mode that is the high image quality mode and the second imaging mode that is the low power consumption mode can be set.

Furthermore, in the first aspect, the pixel circuit may include a charge-voltage conversion unit that converts charges photoelectrically converted by the photoelectric conversion unit into a voltage, form a source follower circuit when the first imaging mode is set, and read the voltage of the charge-voltage conversion unit to the second signal line by the source follower circuit. This brings about an effect that a captured image with relatively high image quality can be acquired when the first imaging mode is set.

Furthermore, in the first aspect, the pixel circuit may include a charge-voltage conversion unit that converts charges photoelectrically converted by the photoelectric conversion unit into a voltage, form a grounded source amplifier when the second imaging mode is set, and read the voltage of the charge-voltage conversion unit to the first signal line by the grounded source amplifier. This brings about an effect that imaging can be performed with relatively low power consumption when the second imaging mode is set.

Furthermore, in the first aspect, the pixel circuit may read a change in potential of the charge-voltage conversion unit as a pulse width of a digital pulse when the second imaging mode is set. This brings about an effect that power consumption can be reduced by reading the change in the potential of the charge-voltage conversion unit as the pulse width of the digital pulse.

Furthermore, in the first aspect, the switching unit may switch to the first imaging mode and perform imaging when detecting an event at the time of imaging in the second imaging mode. This brings about an effect that power consumption can be reduced until an event is detected, and a captured image having a relatively high image quality can be acquired after the event is detected.

Furthermore, in the first aspect, a current of the current source may be set to a slope shape that linearly changes with time with a predetermined inclination when the second imaging mode is set. This brings about an effect that since the potential of the charge-voltage conversion unit exceeds the threshold level and the light intensity can be detected even at low illuminance, the dynamic range can be improved.

Furthermore, in the first aspect, a sample-and-hold circuit that samples and holds a pixel signal output from the pixel circuit when the first imaging mode is set may further be provided. This brings about an effect that both reduction in power consumption and improvement in image quality of a captured image can be achieved even in an imaging device including a sample-and-hold circuit.

Furthermore, in the first aspect, in a case where the pixel circuit further includes a reset transistor that resets the charge-voltage conversion unit, a power supply voltage to be applied to the amplification transistor and a power supply voltage to be applied to the reset transistor may be set to be different power supply voltages. This brings about an effect that it is possible to achieve both reduction in power consumption and improvement in image quality of a captured image even in an imaging device in which a power supply voltage applied to the amplification transistor and a power supply voltage applied to the reset transistor are different.

Furthermore, a second aspect of the present technology is an electronic device including an imaging device including: a pixel circuit including a photoelectric conversion unit and an amplification transistor having a gate electrode connected to the photoelectric conversion unit; a first signal line connected to one electrode side of the amplification transistor; a switching unit connected to the first signal line; a second signal line connected to another electrode side of the amplification transistor; a comparator having a comparison input end connected to the second signal line; a selector connected to the first signal line and an output end of the comparator; and a counter connected to an output end of the selector, in which the switching unit includes a first switch element selectively connecting the first signal line to a power supply, and a second switch element selectively connecting the first signal line to a current source. This brings about an effect that it is possible to achieve both reduction in power consumption and improvement in image quality of a captured image.

### BRIEF DESCRIPTION OF DRAWINGS

FIG. 1 is a system configuration diagram illustrating a configuration example of an imaging device according to a first embodiment of the present technology.

FIG. 2 is an explanatory diagram of an imaging mode of the imaging device according to the first embodiment of the present technology.

FIG. 3 is a circuit diagram illustrating a circuit example of a pixel circuit, a switching unit for one pixel column, and an analog-to-digital conversion circuit of the imaging device according to the first embodiment of the present technology.

FIG. 4 is a timing chart for describing an operation example in a first imaging mode of the imaging device according to the first embodiment of the present technology.

FIG. 5 is a timing chart for describing an operation example in a second imaging mode of the imaging device according to the first embodiment of the present technology.

FIG. 6 is an exploded perspective view schematically illustrating a laminated chip structure 1 of a semiconductor chip structure of the imaging device according to the first embodiment of the present technology.

FIG. 7 is an exploded perspective view schematically illustrating a laminated chip structure 2 of the semiconductor chip structure of the imaging device according to the first embodiment of the present technology.

FIG. 8 is a circuit diagram illustrating an arrangement example of a pixel circuit, a switching unit, and an analog-to-digital conversion circuit corresponding to the laminated chip structure 2.

FIG. 9 is a timing chart for describing an operation example in a second imaging mode of an imaging device according to a second embodiment of the present technology.

FIG. 10 is a system configuration diagram illustrating a configuration example of an imaging device according to a third embodiment of the present technology.

FIG. 11 is a circuit diagram illustrating a circuit example of a pixel circuit, a sample-and-hold circuit for one pixel column, a switching unit, and an analog-to-digital conversion circuit of the imaging device according to the third embodiment of the present technology.

FIG. 12 is a timing chart for describing an operation example in a second imaging mode of the imaging device in the third embodiment of the present technology.

FIG. 13 is a circuit diagram illustrating a circuit example of a pixel circuit, a sample-and-hold circuit for one pixel column, a switching unit, and an analog-to-digital conversion circuit of an imaging device according to a fourth embodiment of the present technology.

FIG. 14 is a diagram illustrating on/off of first to fourth switch elements in each imaging mode and a relationship with each connection destination power supply of a reset transistor and an amplification transistor.

FIG. 15 is a block diagram illustrating a configuration example of a camera system which is an example of an electronic device to which the present technology is applied.

FIG. 16 is a block diagram illustrating a schematic configuration example of a vehicle control system.

FIG. 17 is an explanatory diagram illustrating an example of an installation position of an imaging section.

### MODE FOR CARRYING OUT THE INVENTION

Hereinafter, modes for carrying out the present technology (hereinafter referred to as embodiments) will be described. The description will be given in the following order. 1. First embodiment (basic configuration example of present technology)
1-1. Configuration example of imaging device
1-2. Circuit example of pixel circuit, switching unit, and analog-to-digital conversion circuit
1-3. Operation example of imaging device
1-4. Semiconductor chip structure
2. Second embodiment (example of improving dynamic range when second imaging mode is set)
3. Third embodiment (application example to imaging device including sample-and-hold circuit that samples and holds pixel signal output when first imaging mode is set)
4. Fourth embodiment (modification of third embodiment: application example to imaging device in which power supply of reset transistor and power supply of amplification transistor are different power supplies)
5. Modification
6. Usage example of imaging device
7. Configuration that can be taken by present technology

### First Embodiment

As an imaging device according to a first embodiment of the present technology, for example, a CMOS image sensor, which is a type of X-Y address system imaging device, can be exemplified. A CMOS image sensor is an imaging device fabricated by applying or partially using a CMOS process. The point that the imaging device is, for example, a CMOS image sensor is similar in each embodiment described later.

### Configuration Example of Imaging Device

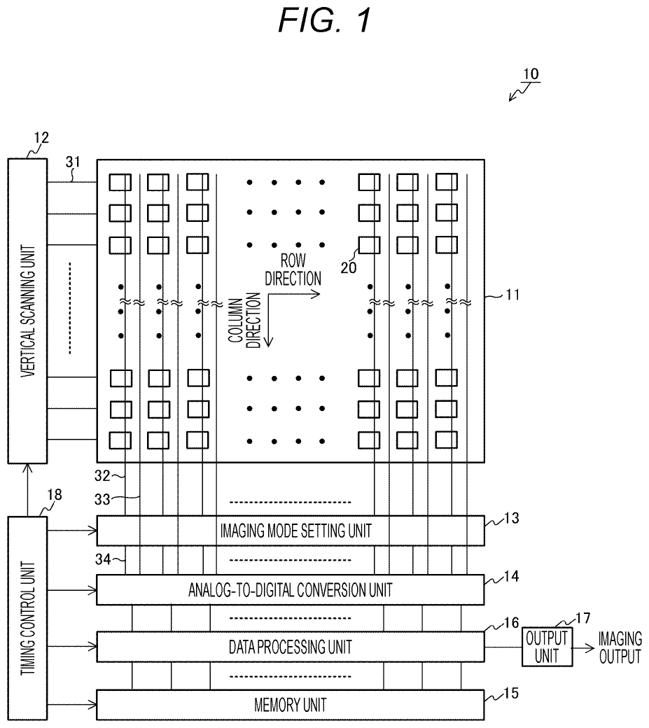

FIG. 1 is a system configuration diagram illustrating a configuration example of an imaging device according to a first embodiment of the present technology. An imaging device 10 according to the first embodiment of the present technology is a basic configuration example of the present technology, and has a configuration including a pixel array unit 11 and a peripheral circuit unit of the pixel array unit 11. The peripheral circuit unit of the pixel array unit 11 includes, for example, a vertical scanning unit 12, an imaging mode setting unit 13, an analog-to-digital conversion unit 14, a memory unit 15, a data processing unit 16, an output unit 17, a timing control unit 18, and the like.

The pixel array unit 11 has a configuration in which pixel circuits (pixels) 20 including photoelectric conversion units (photoelectric conversion elements) are two-dimensionally arranged in a row direction and a column direction, that is, in a matrix. Here, the row direction refers to the arrangement direction of the pixel circuits 20 in a pixel row, and the column direction refers to the arrangement direction of the pixel circuits 20 in a pixel column. The pixel circuit 20 performs photoelectric conversion in the photoelectric conversion unit to generate and accumulate photoelectric charges corresponding to the amount of incident light. In the example illustrated in FIG. 1, the pixel array of the pixel array unit 11 is a pixel array of m rows and n columns (m and n are integers). That is, “m” represents the number of rows, and “n” represents the number of columns.

In the pixel array unit 11, a pixel control line 31 is wired for every pixel row, for the pixel array of m rows and n columns. In addition, a first signal line 32 and a second signal line 33 are wired for each pixel column.

When reading a signal from the pixel circuit 20, the pixel control line 31 transmits a drive signal output from the vertical scanning unit 12 in units of pixel rows. In FIG. 1, the pixel control line 31 is illustrated as one wiring line, but the number thereof is not limited to one. One end of the pixel control line 31 is connected to an output end corresponding to each row of the vertical scanning unit 12. The first signal line 32 transmits a signal read from the pixel circuit 20 to the imaging mode setting unit 13. The second signal line 33 transmits a signal read from the pixel circuit 20 to the analog-to-digital conversion unit 14.

Hereinafter, each component of the peripheral circuit unit of the pixel array unit 11, that is, the vertical scanning unit 12, the imaging mode setting unit 13, the analog-to-digital conversion unit 14, the memory unit 15, the data processing unit 16, the output unit 17, and the timing control unit 18 will be described.

The vertical scanning unit 12 includes a shift register, an address decoder, and the like, and controls scanning of a pixel row and an address of the pixel row on the basis of a timing control signal supplied from the timing control unit 18 at a time of selecting each pixel circuit 20 of the pixel array unit 11. Although a specific configuration of the vertical scanning unit 12 is not illustrated, the vertical scanning unit 12 generally includes two scanning systems of a read scanning system and a sweep scanning system.

The read scanning system sequentially and selectively scans the pixel circuits 20 in the pixel array unit 11 row by row in order to read a pixel signal from the pixel circuit 20. The pixel signal read from the pixel circuit 20 is an analog signal. The sweep scanning system performs sweep scanning on a read row to be subjected to read scanning by the read scanning system earlier than the read scanning by a time corresponding to a shutter speed.

When the sweep scanning is performed by the sweep scanning system, unnecessary charges are swept from the photoelectric conversion units of the pixel circuits 20 in the read row. Therefore, the photoelectric conversion units are reset. Then, when the sweep scanning system sweeps (resets) unnecessary charges, a so-called electronic shutter operation is performed. Here, the electronic shutter operation refers to an operation of discharging photoelectric charges of the photoelectric conversion unit and newly starting exposure (starting accumulation of photoelectric charges).

The signal read by the read operation by the read scanning system corresponds to the amount of light received after the immediately preceding read operation or electronic shutter operation. Then, a period from a read timing in the immediately preceding read operation or sweep timing in the immediately preceding electronic shutter operation to the read timing in the current read operation is an exposure period of photocharges in the pixel circuit 20.

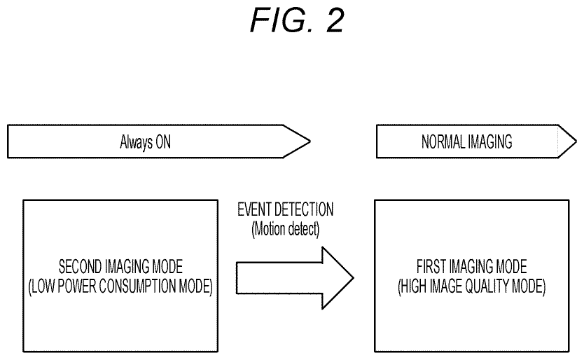

As illustrated in FIG. 2, the imaging device 10 according to the first embodiment is configured to be able to set a first imaging mode that is a high image quality mode and a second imaging mode that is a low power consumption mode. For example, in a place where there is no outlet or power supply equipment in an installation place of the camera system including the imaging device 10, such as a high place, a narrow space, or the outdoors, a battery is used as a drive source. In a case where the imaging device 10 is always in the imaging state (i.e., always ON) in battery driving, the second imaging mode, which is the low power consumption mode, is set to reduce power consumption. Then, when an event is detected, the mode is switched to the first imaging mode, which is a high image quality mode for acquiring a high resolution captured image in all pixels, to acquire a high definition captured image.

The imaging mode setting unit 13 appropriately sets the first imaging mode and the second imaging mode. Details of the first imaging mode and the second imaging mode, and details of setting of the first imaging mode and the second imaging mode by switching control of the imaging mode setting unit 13 will be described later.

The analog-to-digital (A/D) conversion unit 14 converts an analog pixel signal read from the pixel circuit 20 to the first signal line 32 and supplied via the imaging mode setting unit 13 or an analog pixel signal read from the pixel circuit 20 to the second signal line 33 and directly supplied from the second signal line 33 into a digital pixel signal.

The memory unit 15 stores the analog-to-digital conversion result in the analog-to-digital conversion unit 14 under the processing by the data processing unit 16.

The data processing unit 16 is a digital signal processing unit that processes the digital pixel signal output from the analog-to-digital conversion unit 14, and performs processing of writing/reading the analog-to-digital conversion result to/from the memory unit 15 and performs various processing on the analog-to-digital conversion result.

The output unit 17 derives a signal processed by the data processing unit 16 as an imaging output.

The timing control unit 18 generates various timing signals, clock signals, control signals, and the like on the basis of a synchronization signal provided from the outside. Then, the timing control unit 18 performs drive control of the vertical scanning unit 12, the imaging mode setting unit 13, the analog-to-digital conversion unit 14, the memory unit 15, the data processing unit 16, and the like on the basis of the generated signals.

### Circuit Example of Pixel Circuit, Switching Unit, and Analog-to-Digital Conversion Circuit

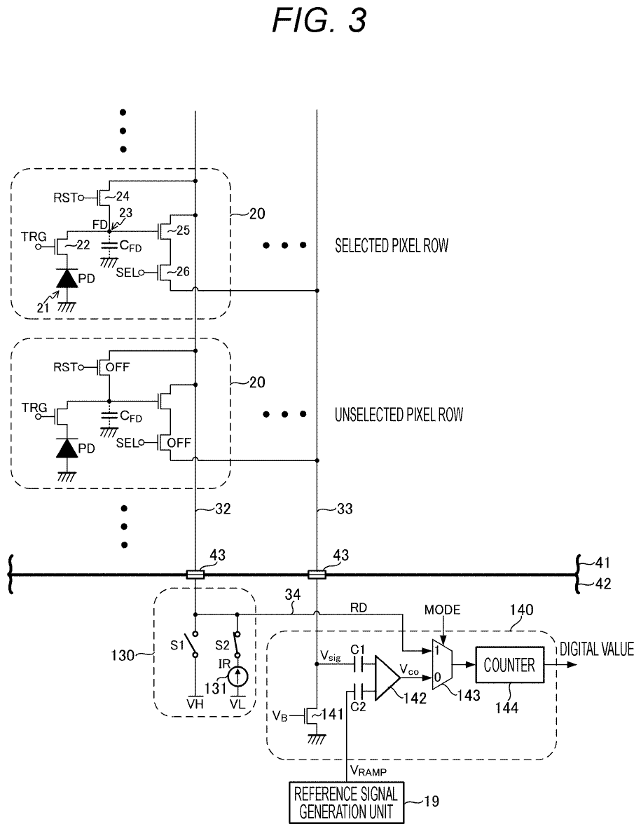

The imaging mode setting unit 13 includes a plurality of switching units 130 provided corresponding to pixel columns of the pixel array unit 11. Furthermore, the analog-to-digital (A/D) conversion unit 14 has a so-called column-parallel analog-to-digital conversion unit configuration including a plurality of analog-to-digital conversion circuits 140 provided corresponding to the pixel columns of the pixel array unit 11. FIG. 3 is a circuit diagram illustrating a circuit example of the pixel circuit 20, the switching unit 130 for one pixel column, and the analog-to-digital conversion circuit 140. FIG. 3 illustrates one pixel circuit 20 of each of a selected pixel row and an unselected pixel row. Note that FIG. 3 illustrates a state (transistor OFF) corresponding to an operation example in the second imaging mode.

### Pixel Circuit

The pixel circuit 20 has a circuit configuration including a photoelectric conversion unit 21, a transfer transistor 22, a charge-voltage conversion unit 23, a reset transistor 24, an amplification transistor 25, and a selection transistor 26.

Here, for example, an N-channel metal oxide semiconductor (MOS) field-effect transistor (hereinafter referred to as a MOS transistor) can be used as the transfer transistor 22, the reset transistor 24, the amplification transistor 25, and the selection transistor 26. However, a combination of conductivity types of the four MOS transistors 22, 24, 25, and 26 exemplified here is merely an example, and the combination is not limited thereto.

For the pixel circuits 20, a plurality of pixel control lines is wired in common to the pixel circuits 20 in the same pixel row as the above-described pixel control lines 31. The plurality of pixel control lines is connected to an output end corresponding to each pixel row of the vertical scanning unit 12, in units of pixel rows. The vertical scanning unit 12 appropriately outputs a transfer signal TRG, a reset signal RST, and a selection signal SEL to the plurality of pixel control lines.

The photoelectric conversion unit 21 is a PN-junction photodiode (PD). The photodiode has an anode electrode connected to a low potential side power supply (for example, ground), and generates and accumulates charges according to an amount of incident light.

The transfer transistor 22 transfers the charges accumulated in the photoelectric conversion unit 21 to the charge-voltage conversion unit 23, in accordance with the transfer signal TRG provided from the vertical scanning unit 12. Specifically, the transfer signal TRG that is active at a high level is supplied from the vertical scanning unit 12 to a gate electrode of the transfer transistor 22. Then, the transfer transistor 22 is turned on and transfers the charges accumulated in the photoelectric conversion unit 21 to the charge-voltage conversion unit 23.

The charge-voltage conversion unit 23 is a capacitance C_{FD} of a floating diffusion (FD) region formed between a drain region of the transfer transistor 22 and a source region of the reset transistor 24. The charge-voltage conversion unit 23 converts the charges transferred from the photoelectric conversion unit 21 by the transfer transistor 22 into a voltage.

The reset transistor 24 has a source electrode connected to the charge-voltage conversion unit 23 and a drain electrode connected to the first signal line 32. A reset signal RST that is active at a high level is provided from the vertical scanning unit 12 to a gate electrode of the reset transistor 24. Then, when the reset signal RST becomes a high level, the reset transistor 24 is turned on to electrically connect the charge-voltage conversion unit 23 and the first signal line 32.

The amplification transistor 25 has a gate electrode connected to the charge-voltage conversion unit 23, a drain electrode connected to the first signal line 32, and a source electrode connected to the second signal line 33 via the selection transistor 26. Note that the drain electrode of the amplification transistor 25 is an example of one electrode described in the claims, and the source electrode is an example of another electrode described in the claims.

The selection transistor 26 selects any pixel circuit 20 in the pixel array unit 11 under selective scanning by the vertical scanning unit 12. The selection transistor 26 is connected between a source electrode of the amplification transistor 25 and the second signal line 33, and the selection signal SEL that is active at a high level is supplied from the vertical scanning unit 12 to a gate electrode of the selection transistor 26. Then, when the selection signal SEL becomes a high level, the selection transistor 26 is turned on to select the pixel circuit 20.

The imaging device 10 according to the first embodiment has, as a semiconductor chip structure, a laminated chip structure in which at least two semiconductor substrates of a first-layer semiconductor substrate 41 and a second-layer semiconductor substrate 42 are laminated, for example. In this laminated chip structure, the pixel circuit 20 and the first and second signal lines 32 and 33 are formed on the first-layer semiconductor substrate 41 side, and the imaging mode setting unit 13 and the analog-to-digital conversion unit 14 are formed on the second-layer semiconductor substrate 42 side. Details of the semiconductor chip structure will be described later.

The first signal line 32 on the first-layer semiconductor substrate 41 and the imaging mode setting unit 13 on the second-layer semiconductor substrate 42 are electrically connected via a connection unit 43 such as a Cu-Cu connection, a through silicon via (TSV), or a microbump. The second signal line 33 on the first-layer semiconductor substrate 41 and the analog-to-digital conversion unit 14 on the second-layer semiconductor substrate 42 are also electrically connected via a similar connection unit 43.

### Switching Unit

The switching unit 130 of the imaging mode setting unit 13 includes a first switch element S1, a second switch element S2, and a current source 131, is provided for each pixel column of the pixel array unit 11, and switches the imaging mode of the imaging device 10. One terminal of the first switch element S1 is electrically connected to the first signal line 32 via the connection unit 43, and the other terminal is connected to a node (power supply node) of a high-potential-side power supply voltage VH. One terminal of the second switch element S2 is electrically connected to the first signal line 32 via the connection unit 43. The current source 131 is connected between the other terminal of the second switch element S2 and a node of a low-potential-side power supply voltage VL. The on/off control of the first switch element S1 and the second switch element S2 is performed by a control signal (not illustrated) provided from the timing control unit 18 illustrated in FIG. 1.

In the switching unit 130 having the above configuration, the first switch element S1 is turned on (closed) and applies the high-potential-side power supply voltage VH to the first signal line 32, thereby setting the first imaging mode in which the image quality of the captured image is relatively high as the imaging mode of the imaging device 10. At this time, the second switch element S2 is in an off (open) state.

In the first imaging mode, the pixel circuit 20 is used as a source follower circuit (grounded drain circuit) by applying the high-potential-side power supply voltage VH to the drain electrodes of the reset transistor 24 and the amplification transistor 25 of the pixel circuit 20 through the first signal line 32. That is, in the first imaging mode, when the pixel circuit 20 forms a source follower circuit, a pixel signal at a level corresponding to the charges accumulated in the charge-voltage conversion unit 23 is read out to the second signal line 33 by the source follower circuit, and supplied to the analog-to-digital conversion circuit 140 through the second signal line 33 and the connection unit 43.

The second switch element S2 is turned on and supplies a current IR of the current source 131 to the first signal line 32, thereby setting the second imaging mode in which power consumption is low at the relative time as the imaging mode of the imaging device 10. At this time, the first switch element S1 is in the OFF state.

In the second imaging mode, the drain electrodes of the reset transistor 24 and the amplification transistor 25 of the pixel circuit 20 are connected to the current source 131 through the first signal line 32, and a load MOS 141 is used as a switch, so that the pixel circuit 20 is used as a grounded source amplifier. That is, in the second imaging mode, when the pixel circuit 20 forms a grounded source amplifier, a change in a potential FD of the charge-voltage conversion unit 23 is supplied to the analog-to-digital conversion circuit 140 through the connection unit 43 and a third signal line 34, so that the change is read as the pulse width of the digital pulse. The operation of reading the change in the potential FD of the charge-voltage conversion unit 23 as the pulse width of the digital pulse is a pulse width modulation (PWM) operation. Details of reading of the pixel signal by the PWM operation will be described later.

Regarding the imaging mode of the imaging device 10, the first imaging mode in which the image quality of the captured image is relatively high is a high image quality mode in which the image quality of the captured image is higher than that of the second imaging mode, and the second imaging mode in which power consumption is relatively low is a low power consumption mode in which power consumption is lower than that of the first imaging mode.

Note that in the pixel circuit 20, the source follower circuit in the first imaging mode has better frequency characteristics than the grounded source amplifier in the second imaging mode.

### Analog-to-Digital Conversion Circuit

The analog-to-digital (A/D) conversion circuit 140 of the analog-to-digital conversion unit 14 can be a well-known analog-to-digital conversion circuit. Specifically, as the analog-to-digital conversion circuit 140, a single-slope analog-to-digital conversion circuit, a successive approximation analog-to-digital conversion circuit, or a delta-sigma (ΔΣ type) analog-to-digital conversion circuit can be exemplified. In the imaging device 10 according to the first embodiment, a single-slope analog-to-digital conversion circuit is used as the analog-to-digital conversion circuit 140.

In the imaging device 10 according to the first embodiment, for example, a so-called single-slope analog-to-digital conversion circuit, which is an example of a reference signal comparison analog-to-digital conversion circuit, is used as the analog-to-digital conversion circuit 140.

In the single-slope analog-to-digital conversion circuit 140, a reference signal of an inclined waveform that linearly changes with time with a predetermined inclination (for example, monotonically decreasing), that is, a reference signal V_{RAMP} of a ramp wave is used as a reference signal at a time of analog-to-digital conversion. The reference signal V_{RAMP} of the ramp wave is generated by a reference signal generation unit 19.

The analog-to-digital conversion circuit 140 includes the load MOS 141, a comparator 142, a selector 143, and a counter 144, and is provided for each pixel column of the pixel array unit 11.

The load MOS 141 is connected between the second signal line 33 and a reference potential node (for example, ground) via the connection unit 43, and forms a source follower circuit together with the amplification transistor 25 of the pixel circuit 20 when the first imaging mode that is the high image quality mode is set.

The comparator 142 uses an analog pixel signal V_{sig} supplied from each pixel circuit 20 of the pixel array unit 11 through the second signal line 33 and input via a capacitive element C1 as a comparison input. In addition, the comparator 142 uses the reference signal V_{RAMP} of the ramp wave generated by the reference signal generation unit 19 and input via a capacitive element C2 as a reference input.

The comparator 142 compares the input signals, and outputs a comparison result V_{co}, for example, at a timing when the reference signal V_{RAMP} of the ramp wave exceeds the voltage value of the analog pixel signal V_{sig}. As a result, the comparator 142 outputs a pulse signal corresponding to the signal level of the analog pixel signal V_{sig}, specifically, a pulse signal having a pulse width corresponding to the magnitude of the signal level of the analog pixel signal V_{sig}, as the comparison result V_{co}.

The selector 143 inputs the pixel signal supplied from the first signal line 32 through the third signal line 34 at the time of setting the second imaging mode that is the low power consumption mode and the comparison result V_{co} of the comparator 142 at the time of setting the second imaging mode that is the high image quality mode, selects any input according to an imaging mode MODE, and supplies the selected input to the counter 144.

A clock signal (not illustrated) is provided from the timing control unit 18 to the counter 144 at the same timing as the supply start timing of the reference signal V_{RAMP} of the ramp wave to the comparator 142. The counter 144 measures the period of the pulse width of the output pulse of the comparator 142, that is, the period from the start of the comparison operation to the end of the comparison operation by performing the counting operation in synchronization with the clock signal provided from the timing control unit 18. The count result (count value) of the counter 144 is supplied to the data processing unit 16 as a digital value obtained by digitizing the analog pixel signal V_{sig}.

As the counter 144, for example, an up/down counter can be used. The counter 144 including the up/down counter performs down (DOWN) counting or up (UP) counting in synchronization with a clock signal provided from the timing control unit 18. Specifically, when the first imaging mode that is the high image quality mode is set, for example, for a reset signal that is output from the pixel circuit 20 and is a reset level at the time of resetting the charge-voltage conversion unit 23 and a data signal that is a signal level based on photoelectric conversion, the reset signal is down-counted, and the data signal is up-counted.

The difference between the data signal and the reset signal can be obtained by the down count/up count operation. As a result, in the analog-to-digital conversion circuit 140, correlated double sampling (CDS) processing is performed in addition to the analog-to-digital conversion processing. Here, the “CDS processing” is processing of removing fixed pattern noise unique to pixels such as reset noise of the pixel circuit 20 and threshold variation of the amplification transistor 25 by obtaining a difference between a data signal that is a signal level based on photoelectric conversion and a reset signal that is a reset level at the time of resetting the charge-voltage conversion unit 23.

As described above, the analog-to-digital conversion unit 14 including the single-slope analog-to-digital conversion circuit 140 compares the analog pixel signal V_{sig} output from the pixel circuit 20 with the reference signal V_{RAMP} of the ramp wave generated by the reference signal generation unit 19. Then, a digital value can be obtained from the time information from the start of the comparison to the timing (that is, the timing at which the output of the comparator 142 is inverted) at which the magnitude relationship between the analog pixel signal Vsig and the reference signal V_{RAMP} of the ramp wave changes.

### Operation Example of Imaging Device

Next, an operation example of the imaging device 10 in the first embodiment, specifically, an operation example in the first imaging mode that is the high image quality mode and an operation example in the second imaging mode that is the low power consumption mode will be described.

### Operation Example in First Imaging Mode

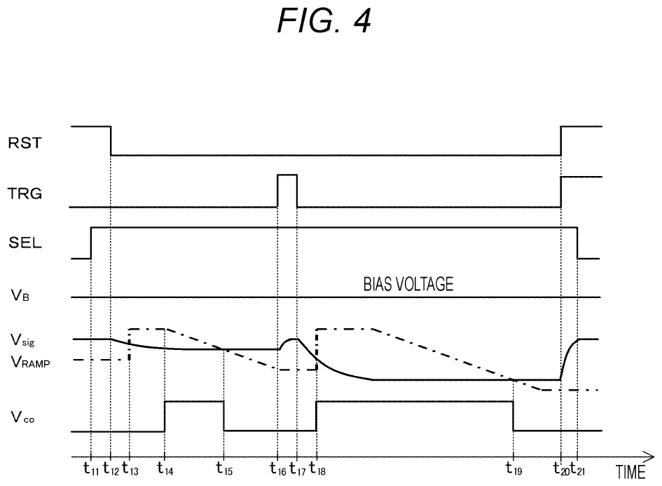

FIG. 4 is a timing chart for describing an operation example in the first imaging mode of the imaging device 10 according to the first embodiment of the present technology.

In the first imaging mode, the first switch element S1 is turned on (closed) in the switching unit 130 of the imaging mode setting unit 13. As a result, the high-potential-side power supply voltage VH is applied to the drain electrodes of the reset transistor 24 and the amplification transistor 25 of the pixel circuit 20. In addition, a predetermined bias voltage is applied to the load MOS 141 as a bias voltage V_{B}. As a result, the pixel circuit 20 operates as a source follower circuit (grounded drain circuit) that reads a pixel signal at a level corresponding to the charges accumulated in the charge-voltage conversion unit 23 to the second signal line 33.

Hereinafter, an operation example in the first imaging mode will be described more specifically. At time t₁₁, the selection signal SEL becomes the high level, and the selection transistor 26 is turned on, so that the pixel circuit 20 of one pixel row enters the selected state.

After reset cancellation of the charge-voltage conversion unit 23 by the reset transistor 24 at time t₁₂, the reference signal V_{RAMP} of the ramp wave is output from the reference signal generation unit 19 at time t₁₃. Then, in the comparator 142, a signal having a pulse width from time t₁₄ to time t₁₅ is acquired as the comparison result V_{co}. The pulse width signal from time t₁₄ to time t₁₅ is a reset signal (so-called P-phase signal) which is a reset level at the time of resetting the charge-voltage conversion unit 23 by the reset transistor 24.

Next, in a period from time t₁₆ to time t₁₇, the transfer signal TRG becomes a high level, and the transfer transistor 22 is turned on, so that the charges based on the photoelectric conversion in the photoelectric conversion unit 21 are transferred to the charge-voltage conversion unit 23. Then, in the comparator 142, a signal having a pulse width from time t₁₈ to time t₁₉ is acquired as the comparison result V_{co}. The signal having the pulse width from time t₁₈ to time t₁₉ is a data signal (so-called D-phase signal) which is a signal level corresponding to the charges based on the photoelectric conversion in the photoelectric conversion unit 21.

The reset signal RST and the transfer signal TRG transition from the low level to the high level at time t₂₀, and the selection signal SEL transition from the high level to the low level at time t₂₁, whereby the readout operation of the pixel signal V_{sig} including the reset signal and the P-phase signal by the source follower circuit in each pixel circuit 20 in the selected pixel row ends.

### Operation Example in Second Imaging Mode

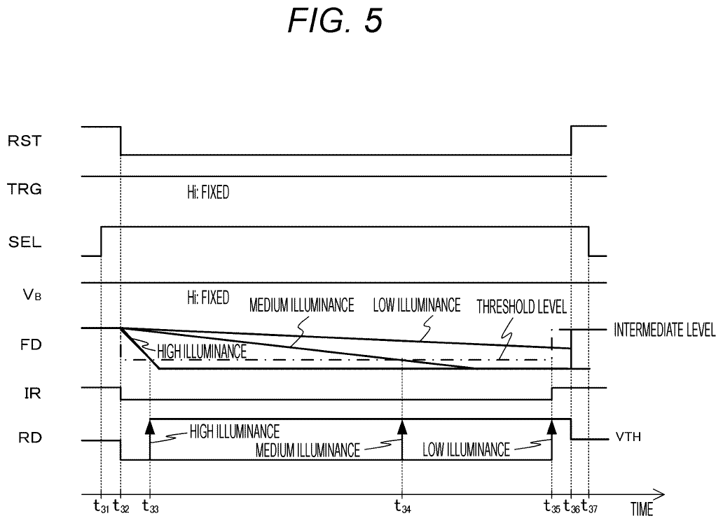

FIG. 5 is a timing chart for describing an operation example in the second imaging mode of the imaging device 10 according to the first embodiment of the present technology.

In the second imaging mode, in the switching unit 130 of the imaging mode setting unit 13, the second switch element S2 is turned on (closed), and the pixel signal is read by the pulse width modulation (PWM) method, whereby power consumption can be reduced.

Specifically, in the PWM operation in the second imaging mode, when the second switch element S2 is turned on, the drain electrodes of the reset transistor 24 and the amplification transistor 25 of the pixel circuit 20 are connected to the current source 131 through the first signal line 32. In addition, the bias voltage V_{B} is fixed to a high level (Hi), and the load MOS 141 is in an ON state. Thus, the pixel circuit 20 operates as a grounded source amplifier. That is, the pixel signal is read out to the first signal line 32 by the grounded source amplifier. At this time, with respect to the pixel circuit 20 of the unselected pixel row, by turning off the reset transistor 24 and the selection transistor 26 (see FIG. 3), it is possible to set only a single pixel row which is the selected pixel row to the active state.

Hereinafter, an operation example in the second imaging mode will be described more specifically. First, when the transfer signal TRG is fixed to the high level and the transfer transistor 22 is in the ON state, the reset signal RST becomes the high level, whereby the reset transistor 24 is turned on, the initialization operation of the charge-voltage conversion unit 23 is performed, and the potential FD of the charge-voltage conversion unit 23 is set to the intermediate level.

After the initialization operation of the charge-voltage conversion unit 23, the selection signal SEL goes to a high level at time t₃₁, so that the selection transistor 26 is turned on, and then the reset signal RST goes to a low level at time t₃₂, so that the reset transistor 24 is turned off. At the same time, the current IR of the current source 131 is lowered (or pulled down), and a potential RD of the third signal line 34 is temporarily set to the low level. The current IR of the current source 131 is a constant current.

When the photoelectric conversion unit 21 is irradiated with light after the reset cancellation by the reset transistor 24, a reverse bias current is generated, and the potential FD of the charge-voltage conversion unit 23 gradually decreases. The decreasing speed of the potential FD at this time increases as the illuminance increases. The timing chart of FIG. 5 schematically illustrates the decreasing speeds of high illuminance, medium illuminance, and low illuminance.

When the potential FD of the charge-voltage conversion unit 23 falls below the threshold level of the grounded source amplifier, the potential RD of the third signal line 34 increases through the first signal line 32. In the example of the timing chart of FIG. 5, the potential RD rises as the potential FD at the high illuminance falls below the threshold level at time t₃₃, the potential RD rises as the potential FD at the medium illuminance falls below the threshold level at time t₃₄, and the potential RD rises as the potential FD at the low illuminance falls below the threshold level at time t₃₅. The illuminance signal can be obtained as the measurement result (pulse width of the digital pulse) of the counter 144 by measuring the timing at which the potential RD rises with the counter 144 through the selector 143.

When the reset signal RST goes to a high level at time t₃₆, the reset transistor 24 is turned on, and then when the selection signal SEL goes to a low level at time t₃₇, the selection transistor 26 is turned on. The series of operations described above is the PWM operation. By this PWM operation, the level of the illuminance signal is converted into the pulse width of the digital pulse.

As described above, in the PWM operation in the second imaging mode of the imaging device 10 in the first embodiment, since the change in the potential FD of the charge-voltage conversion unit 23 is read (read out) as the pulse width of the digital pulse, the power supply voltage of the pixel circuit 20 can be lowered. As a result, in the second imaging mode, power consumption of the imaging device 10 can be reduced by the PWM operation.

### Semiconductor Chip Structure

Next, a semiconductor chip structure of the imaging device 10 according to the first embodiment will be described. As a semiconductor chip structure of the imaging device 10, a flat chip structure in which a peripheral circuit unit of the pixel array unit 11 is formed on the same semiconductor substrate as the pixel circuit 20 can be adopted. However, in the imaging device 10 according to the first embodiment, a laminated chip structure in which at least two semiconductor substrates of the first-layer semiconductor substrate 41 and the second-layer semiconductor substrate 42 are laminated is adopted.

In this laminated chip structure, by arranging the pixel circuit 20 on the first-layer semiconductor substrate 41 and arranging the peripheral circuit unit on the second-layer semiconductor substrate 42, a process suitable for fabricating the pixel circuit 20 can be applied to the first-layer semiconductor substrate 41, and a process suitable for fabricating the circuit portion can be applied to the second-layer semiconductor substrate 42. As a result, the process can be optimized in manufacturing the imaging device 10. In particular, an advanced process can be applied when fabricating the circuit portion.

Hereinafter, a laminated chip structure 1 and a laminated chip structure 2 will be described as specific examples of the laminated chip structure. The specific example of the laminated chip structure is similarly applicable to each embodiment described later.

### Laminated Chip Structure 1

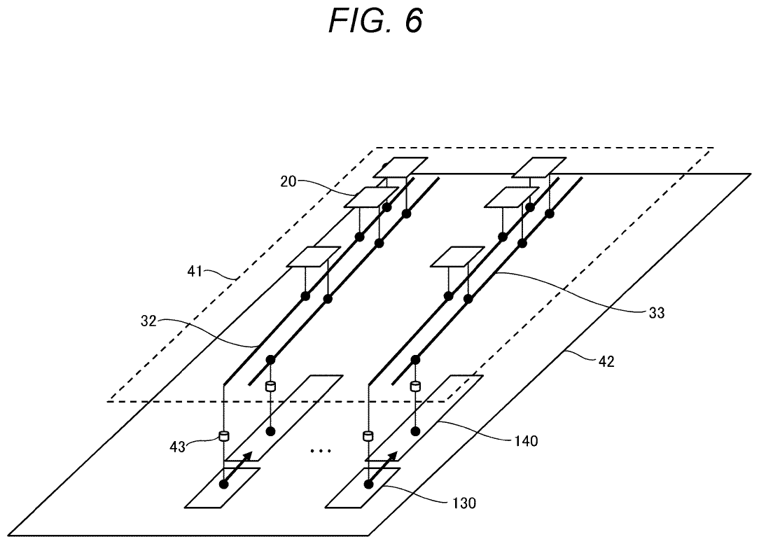

FIG. 6 is an exploded perspective view schematically illustrating the laminated chip structure 1 of the semiconductor chip structure of the imaging device according to the first embodiment of the present technology. The laminated chip structure 1 corresponds to the circuit configuration illustrated in FIG. 3, and has a structure in which at least two semiconductor substrates of the first-layer semiconductor substrate 41 and the second-layer semiconductor substrate 42 are laminated.

In the laminated chip structure 1, the first-layer semiconductor substrate 41 is a pixel chip in which pixel circuits 20 including photoelectric conversion units (for example, a photodiode) are two-dimensionally arranged in a matrix. On the first-layer semiconductor substrate 41, the first signal line 32 and the second signal line 33 are wired for each pixel column.

The second-layer semiconductor substrate 42 is a logic chip on which a peripheral circuit unit of the pixel array unit 11, that is, the imaging mode setting unit 13 including the switching unit 130, the analog-to-digital conversion unit 14 including the analog-to-digital conversion circuit 140, and the like are formed.

The first signal line 32 and the second signal line 33 to which the pixel circuit 20 is electrically connected on the first-layer semiconductor substrate 41, and the switching unit 130 and the analog-to-digital conversion circuit 140 on the second-layer semiconductor substrate 42 are electrically connected via the connection unit 43 such as a Cu-Cu connection, a through silicon via (TSV), or a microbump.

As described above, the laminated chip structure 1 corresponds to the circuit configuration illustrated in FIG. 3, and has a configuration in which the switching unit 130 and the analog-to-digital conversion circuit 140 are arranged in the logic chip which is the second-layer semiconductor substrate 42.

### Laminated Chip Structure 2

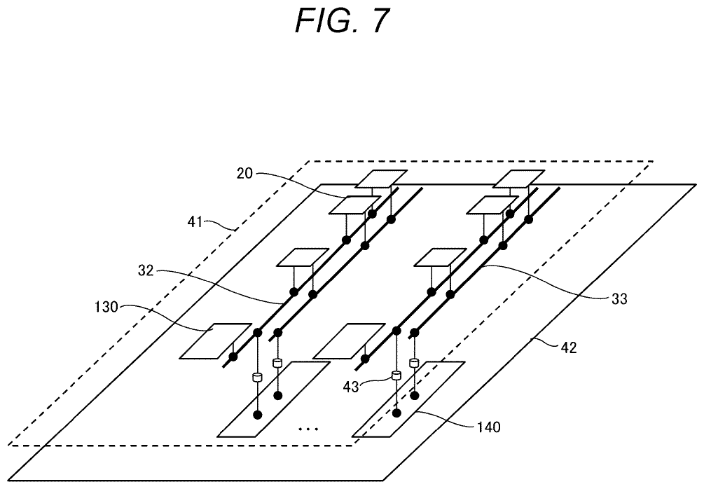

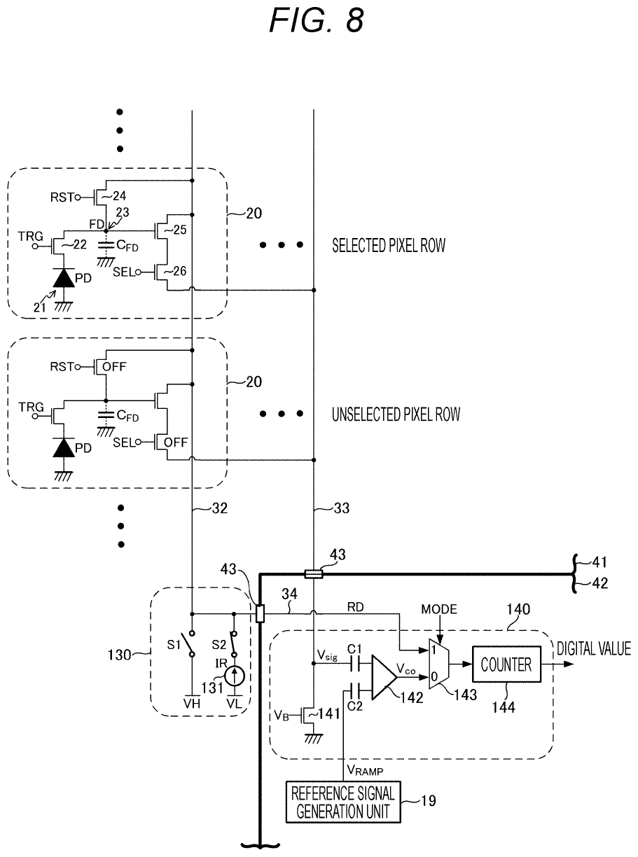

FIG. 7 is an exploded perspective view schematically illustrating the laminated chip structure 2 of the semiconductor chip structure of the imaging device according to the first embodiment of the present technology. The laminated chip structure 2 corresponds to the circuit configuration illustrated in FIG. 8. FIG. 8 is a circuit diagram illustrating an arrangement example of the pixel circuit 20, the switching unit 130, and the analog-to-digital conversion circuit 140 corresponding to the laminated chip structure 2. Similarly to the laminated chip structure 1, the laminated chip structure 2 also has a structure in which at least two semiconductor substrates of the first-layer semiconductor substrate 41 and the second-layer semiconductor substrate 42 are laminated.

In the laminated chip structure 2, in the first-layer semiconductor substrate 41 which is a pixel chip, pixel circuits 20 including photoelectric conversion units (for example, a photodiode) are two-dimensionally arranged in a matrix. On the first-layer semiconductor substrate 41, the first signal line 32 and the second signal line 33 are wired for each pixel column. In the laminated chip structure 2, the switching unit 130 is further formed on the first-layer semiconductor substrate 41.

The second-layer semiconductor substrate 42 which is a logic chip is a logic chip on which, for example, the analog-to-digital conversion circuit 140 and the like are formed among the peripheral circuit units of the pixel array unit 11. Then, the first signal line 32 and the second signal line 33 on the first-layer semiconductor substrate 41 and the analog-to-digital conversion circuit 140 on the second-layer semiconductor substrate 42 are electrically connected via the connection unit 43 such as Cu-Cu connection.

As described above, the laminated chip structure 2 corresponds to the circuit configuration illustrated in FIG. 8, and has a configuration in which the switching unit 130 is arranged in the pixel chip which is the first-layer semiconductor substrate 41, and the analog-to-digital conversion circuit 140 is arranged in the logic chip which is the second-layer semiconductor substrate 42.

### Second Embodiment

A second embodiment of the present technology is an example of improving the dynamic range when a second imaging mode that is a low power consumption mode is set. Note that an overall configuration of an imaging device 10 is similar to that of the first embodiment described above, and thus detailed description is omitted.

In the imaging device 10 in the first embodiment described above, the current IR of the current source 131 is set to a constant current when the second imaging mode that is the low power consumption mode is set. When the current IR of the current source 131 is a constant current, all low-illuminance signals in which the potential FD of the charge-voltage conversion unit 23 does not exceed the threshold level are regarded as the same intensity.

Therefore, in the imaging device 10 according to the second embodiment of the present technology, when the second imaging mode that is the low power consumption mode is set, a current IR of a current source 131 has a slope shape that linearly changes with time with a predetermined inclination. By making the current IR of the current source 131 in a slope shape, a potential FD of a charge-voltage conversion unit 23 exceeds the threshold level and light intensity can be detected even at low illuminance, so that the dynamic range can be improved.

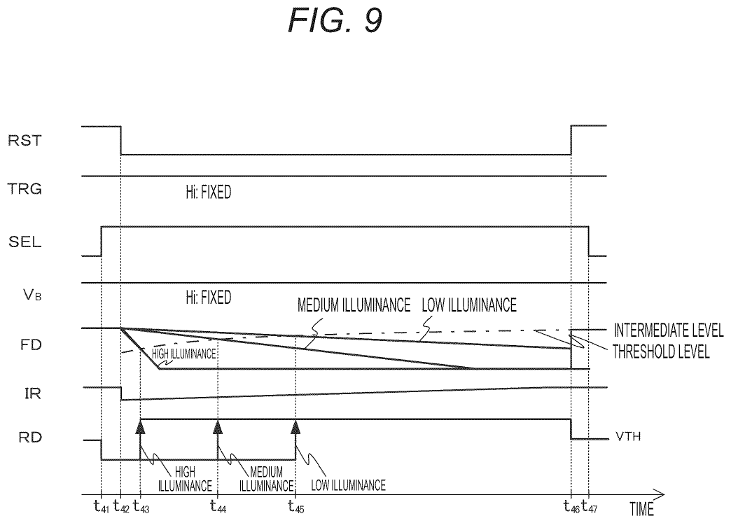

FIG. 9 is a timing chart for describing an operation example in the second imaging mode of the imaging device according to the second embodiment of the present technology. Note that the operation in the first imaging mode of the imaging device in the second embodiment is similar to the operation in the first imaging mode of the imaging device in the first embodiment.

First, when the transfer signal TRG is fixed to the high level and the transfer transistor 22 is in the ON state, the reset signal RST becomes the high level, whereby the reset transistor 24 is turned on, the initialization operation of the charge-voltage conversion unit 23 is performed, and the potential FD of the charge-voltage conversion unit 23 is set to the intermediate level.

After the initialization operation of the charge-voltage conversion unit 23, a selection signal SEL goes to a high level at time t₄₁, so that a selection transistor 26 is turned on, and then a reset signal RST goes to a low level at time t₄₂, so that the reset transistor 24 is turned off. At the same time, the current IR of the current source 131 is increased in a slope shape to the current at the time of initialization.

When the photoelectric conversion unit 21 is irradiated with light after the reset cancellation by the reset transistor 24, a reverse bias current is generated, and the potential FD of the charge-voltage conversion unit 23 gradually decreases. The decreasing speed of the potential FD at this time increases as the illuminance increases. The timing chart of FIG. 9 schematically illustrates the decreasing speeds of high illuminance, medium illuminance, and low illuminance.

When the potential FD of the charge-voltage conversion unit 23 falls below the threshold level of the grounded source amplifier, a potential RD of a third signal line 34 increases. In the example of the timing chart of FIG. 9, the potential RD rises as the potential FD at the high illuminance falls below the threshold level at time t₄₃, the potential RD rises as the potential FD at the medium illuminance falls below the threshold level at time t₄₄, and the potential RD rises as the potential FD at the low illuminance falls below the threshold level at time t₄₅. The illuminance signal can be obtained as the measurement result (pulse width of the digital pulse) of the counter 144 by measuring the timing at which the potential RD rises with the counter 144 through the selector 143.

When the reset signal RST goes to a high level at time t₄₆, the reset transistor 24 is turned on, and then when the selection signal SEL goes to a low level at time t₄₇, the selection transistor 26 is turned on. The series of operations described above is the PWM operation. By this PWM operation, the level of the illuminance signal is converted into the pulse width of the digital pulse.

As described above, in the PWM operation in the second imaging mode of the imaging device 10 in the second embodiment, since the change in the potential FD of the charge-voltage conversion unit 23 is read (read out) as the pulse width of the digital pulse, the power supply voltage of the pixel circuit can be lowered. Therefore, in the second imaging mode, power consumption of the imaging device 10 can be reduced by the PWM operation. Furthermore, by making the current IR of the current source 131 in a slope shape, the threshold level of the grounded source amplifier changes according to the current IR, so that the potential FD of the charge-voltage conversion unit 23 exceeds the threshold level even at low illuminance, and the intensity can be detected. As a result, the dynamic range can be improved.

### Third Embodiment

A third embodiment of the present technology is an application example to an imaging device including a sample-and-hold circuit that samples and holds a pixel signal output when a first imaging mode is set.

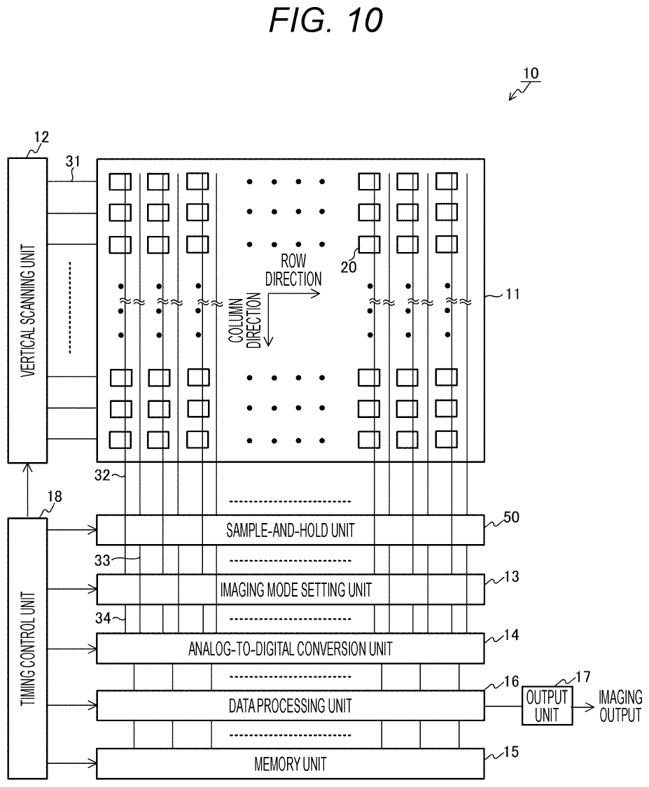

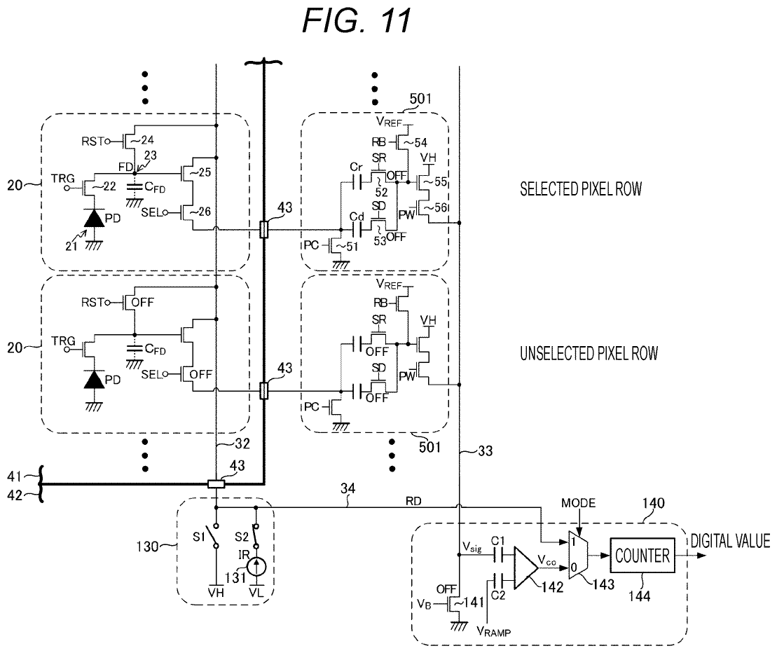

FIG. 10 is a system configuration diagram illustrating a configuration example of an imaging device according to the third embodiment of the present technology. FIG. 11 is a circuit diagram illustrating a circuit example of a pixel circuit, a sample-and-hold circuit for one pixel column, a switching unit, and an analog-to-digital conversion circuit of an imaging device according to the third embodiment. Note that FIG. 11 illustrates a state (transistor OFF) corresponding to an operation example in a second imaging mode to be described later.

An imaging device 10 according to the third embodiment of the present technology includes a sample-and-hold unit 50 that samples and holds a pixel signal output from a pixel circuit 20 by a source follower circuit when the first imaging mode is set. The sample-and-hold unit 50 is provided to implement a global shutter (electronic shutter for all pixels collectively) that starts exposure at the same timing and ends exposure at the same timing for all pixels, and has a configuration including, for example, a plurality of sample-and-hold circuits 501 provided corresponding to pixel columns of a pixel array unit 11.

The plurality of sample-and-hold circuits 501 is formed on a second-layer semiconductor substrate 42, and is electrically connected to pixel circuits 20 of corresponding pixel columns on a first-layer semiconductor substrate 41 via a connection unit 43.

The sample-and-hold circuit 501 includes an input transistor 51, a D-phase capacitive element Cd, a P-phase capacitive element Cr, a P-phase transistor 52, a D-phase transistor 53, a connection transistor 54, an amplification transistor 55, and a selection transistor 56. As transistors in the sample-and-hold circuit 501, for example, N-channel MOS transistors can be used. However, the combination of conductivity types of the MOS transistors herein exemplified is merely an example, and the combination is not limited thereto.

In the sample-and-hold circuit 501, when the P-phase signal that is a reset signal is output from the pixel circuit 20, sampling and holding of the P-phase signal level with respect to the P-phase capacitive element Cr is performed under the control of a control signal SR. Furthermore, when a D-phase signal that is a data signal is output from the pixel circuit 20, sampling and holding of the D-phase signal with respect to the D-phase capacitive element Cd are performed under the control of a control signal SD.

These operations are performed simultaneously for all the pixels. That is, exposure is performed by the global shutter method. In this global shutter method, timings of start and end of exposure of all pixels are completely matched.

Note that in the case of the imaging device 10 according to the third embodiment of the present technology, a second signal line 33 is wired on the second-layer semiconductor substrate 42 as is the plurality of sample-and-hold circuits 501.

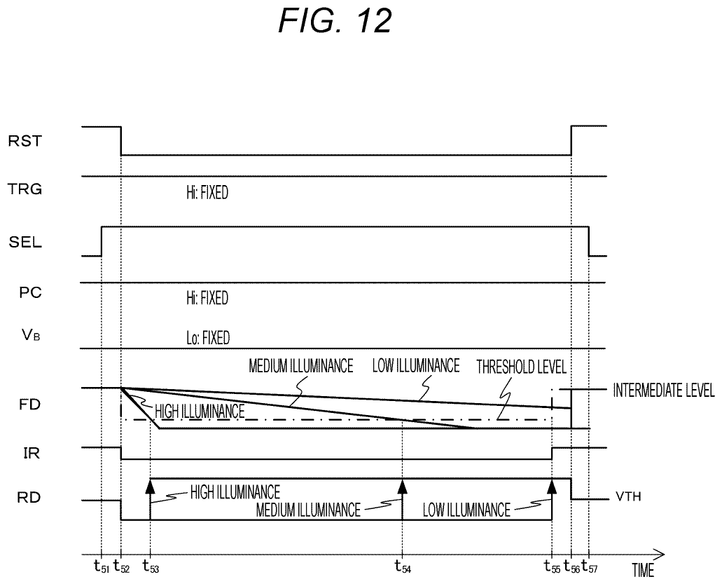

FIG. 12 is a timing chart for describing an operation example in the second imaging mode of the imaging device according to the third embodiment of the present technology. Note that the operation in the first imaging mode of the imaging device 10 in the third embodiment is basically similar to the operation in the first imaging mode of the imaging device 10 in the first embodiment.

In the second imaging mode of the imaging device in the third embodiment, when a second switch element S2 is turned on, drain electrodes of a reset transistor 24 and an amplification transistor 25 of the pixel circuit 20 are connected to a current source 131 through a first signal line 32. In addition, when a bias voltage V_{B} is fixed to a low level (Lo), a load MOS 141 is turned off, and instead, when a control signal PC is fixed to a high level (Hi), an input transistor 51 of the sample-and-hold circuit 501 is turned on.

Thus, the pixel circuit 20 operates as a grounded source amplifier. That is, the pixel signal is read out to the first signal line 32 by the grounded source amplifier. At this time, with respect to the pixel circuit 20 of the unselected pixel row, by turning off the reset transistor 24 and the selection transistor 26, it is possible to set only a single pixel row which is the selected pixel row to the active state.

Hereinafter, an operation example in the second imaging mode will be described more specifically. First, when the transfer signal TRG is fixed to the high level and the transfer transistor 22 is in the ON state, the reset signal RST becomes the high level, whereby the reset transistor 24 is turned on, the initialization operation of the charge-voltage conversion unit 23 is performed, and the potential FD of the charge-voltage conversion unit 23 is set to the intermediate level.

After the initialization operation of the charge-voltage conversion unit 23, a selection signal SEL goes to a high level at time t₅₁, so that a selection transistor 26 is turned on, and then a reset signal RST goes to a low level at time t₅₂, so that the reset transistor 24 is turned off. At the same time, the current IR of the current source 131 is lowered (or pulled down), and a potential RD of the third signal line 34 is temporarily set to the low level.

When the photoelectric conversion unit 21 is irradiated with light after the reset cancellation by the reset transistor 24, a reverse bias current is generated, and the potential FD of the charge-voltage conversion unit 23 gradually decreases. The decreasing speed of the potential FD at this time increases as the illuminance increases. The timing chart of FIG. 12 schematically illustrates the decreasing speeds of high illuminance, medium illuminance, and low illuminance.

When the potential FD of the charge-voltage conversion unit 23 falls below the threshold level of the grounded source amplifier, the potential RD of the third signal line 34 increases through the first signal line 32. In the example of the timing chart of FIG. 12, the potential RD rises as the potential FD at the high illuminance falls below the threshold level at time t₅₃, the potential RD rises as the potential FD at the medium illuminance falls below the threshold level at time t₅₄, and the potential RD rises as the potential FD at the low illuminance falls below the threshold level at time t₅₅. The illuminance signal can be obtained as the measurement result (pulse width of the digital pulse) of the counter 144 by measuring the timing at which the potential RD rises with the counter 144 through the selector 143.

When the reset signal RST goes to a high level at time t₅₆, the reset transistor 24 is turned on, and then when the selection signal SEL goes to a low level at time t₅₇, the selection transistor 26 is turned on. The series of operations described above is the PWM operation. By this PWM operation, the level of the illuminance signal is converted into the pulse width of the digital pulse.

As described above, also in the imaging device 10 in the third embodiment having a configuration including the sample-and-hold unit 50 that samples and holds the pixel signal output when the first imaging mode is set, similarly to the imaging device 10 in the first embodiment, in the first imaging mode, a captured image with relatively high image quality can be obtained, and the PWM operation can be performed in the second imaging mode. In this PWM operation, since the change in the potential FD of the charge-voltage conversion unit 23 is read (read out) as the pulse width of the digital pulse, the power supply voltage of the pixel circuit can be lowered. Therefore, also in the second imaging mode of the imaging device 10 in the third embodiment, power consumption of the imaging device 10 can be reduced by the PWM operation.

### Fourth Embodiment

A fourth embodiment of the present technology is a modification of the third embodiment, and is an application example to an imaging device in which a power supply of a reset transistor and a power supply of an amplification transistor in a pixel circuit are different power supplies.

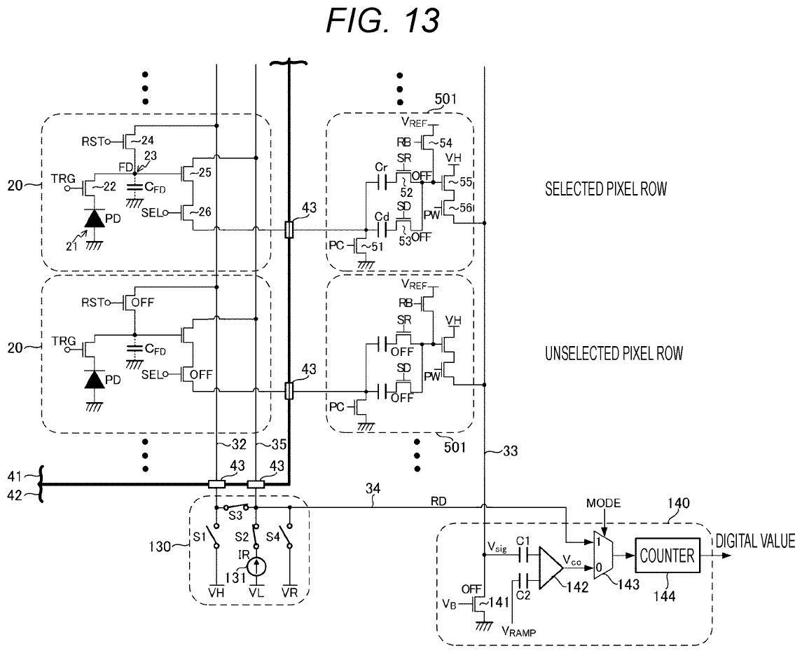

FIG. 13 is a circuit diagram illustrating a circuit example of a pixel circuit, a sample-and-hold circuit for one pixel column, a switching unit, and an analog-to-digital conversion circuit of an imaging device according to a fourth embodiment of the present technology.

On a first-layer semiconductor substrate 41 in which pixel circuits 20 are two-dimensionally arranged in a matrix, in addition to a first signal line 32, a fourth signal line 35 is wired for each pixel column. The fourth signal line 35 is electrically connected to a switching unit 130 on a second-layer semiconductor substrate 42 via a connection unit 43. In addition to nodes of a high-potential-side power supply voltage VH and a low-potential-side power supply voltage VL, the switching unit 130 is provided with a node of a high-potential-side power supply voltage VR different from the high-potential-side power supply voltage VH.

On the first-layer semiconductor substrate 41, the drain electrode of a reset transistor 24 of the pixel circuit 20 is electrically connected to the first signal line 32, and the drain electrode of an amplification transistor 25 of the pixel circuit 20 is electrically connected to the fourth signal line 35.

On the second-layer semiconductor substrate 42, the switching unit 130 electrically connected to the fourth signal line 35 via the connection unit 43 includes a third switch element S3 and a fourth switch element S4 in addition to a first switch element S1, a second switch element S2, and a current source 131.

The third switch element S3 is connected between the first switch element S1 electrically connected to the first signal line 32 and the second switch element S2 electrically connected to the fourth signal line 35. The fourth switch element S4 is connected between a node of the high-potential-side power supply voltage VR different from the high-potential-side power supply voltage VH and the second switch element S2.

The on/off control of the first to fourth switch elements S1 to S4 is performed by a control signal (not illustrated) provided from a timing control unit 18 illustrated in FIG. 10. In addition, a first imaging mode and a second imaging mode are set by turning on/off the first to fourth switch elements S1 to S4, and a global shutter mode and a signal reading mode are switched in the first imaging mode.

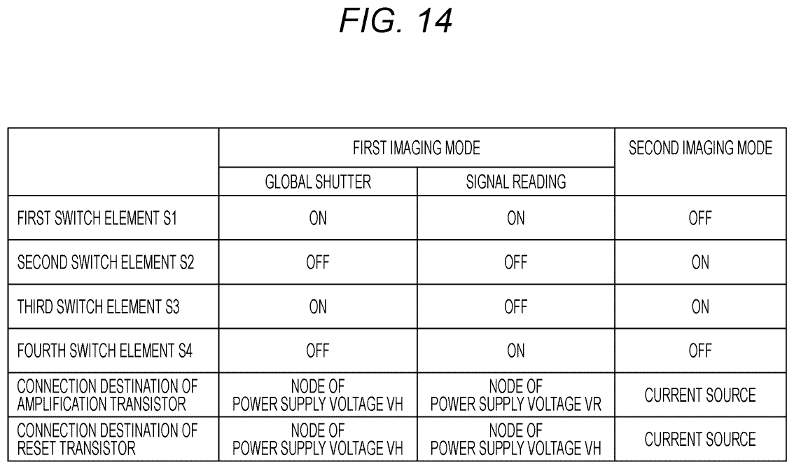

FIG. 14 is a diagram illustrating on/off of the first to fourth switch elements S1 to S4 in each imaging mode and a relationship with each connection destination power supply of the reset transistor 24 and the amplification transistor 25.

The global shutter mode of the first imaging mode is set when the first switch element S1 is turned on, the second switch element S2 is turned off, the third switch element S3 is turned on, the fourth switch element S4 is turned off, and the connection destination of the reset transistor 24 and the amplification transistor 25 is the node of a power supply voltage VH.

The signal reading mode of the first imaging mode is set when the first switch element S1 is turned on, the second switch element S2 is turned off, the third switch element S3 is turned off, the fourth switch element S4 is turned on, the connection destination of the amplification transistor 25 is the node of a power supply voltage VR, and the connection destination of the reset transistor 24 is the node of the power supply voltage VH.

The second imaging mode of the PWM operation that is the low power consumption mode is set when the first switch element S1 is turned off, the second switch element S2 is turned on, the third switch element S3 is turned on, the fourth switch element S4 is turned off, and the connection destination of the reset transistor 24 and the amplification transistor 25 is the current source 131.

As described above, also in the imaging device 10 in the fourth embodiment in which the power supply of the reset transistor 24 and the power supply of the amplification transistor 25 in the pixel circuit 20 are different power supplies, similarly to the imaging device 10 in the first embodiment, a captured image with relatively high image quality can be obtained in the first imaging mode, and the PWM operation can be performed in the second imaging mode. In this PWM operation, since the change in the potential FD of the charge-voltage conversion unit 23 is read (read out) as the pulse width of the digital pulse, the power supply voltage of the pixel circuit can be lowered. Therefore, also in the second imaging mode of the imaging device 10 in the fourth embodiment, power consumption of the imaging device 10 can be reduced by the PWM operation.

### Modification

Note that the embodiments described above illustrate examples for embodying the present technology, and the matters in the embodiments and the matters specifying the invention in the claims have correspondence relationships. Similarly, the matters specifying the invention in the claims and matters with the same names in the embodiments of the present technology have correspondence relationships. However, the present technology is not limited to the embodiments, and can be embodied by applying various modifications to the embodiments without departing from the scope of the present technology.

### Example of Application to Electronic Device

The imaging device according to the embodiments of the present technology described above can be applied to various electronic devices having an imaging function such as a camera system of a monitoring camera, an in-vehicle camera, or the like.

### Example of Camera System

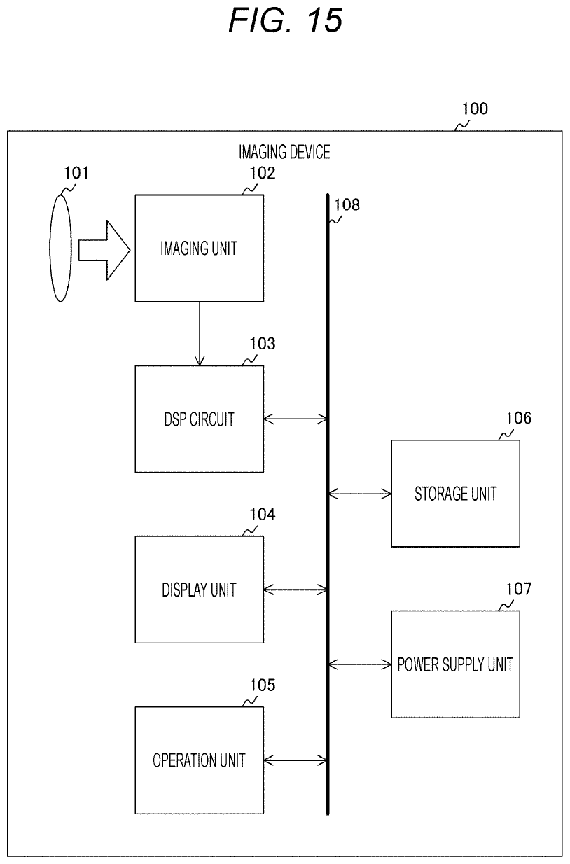

FIG. 15 is a block diagram illustrating a configuration example of a camera system which is an example of an electronic device to which the present technology is applied.

A camera system 100 according to the present application example is a device for imaging a subject, and includes an imaging optical system 101 including a lens group and the like, an imaging unit 102, a digital signal processor (DSP) circuit 103, a display unit 104, an operation unit 105, a storage unit 106, and a power supply unit 107. These components are connected to one another by a bus 108. As the camera system 100, for example, a monitoring camera, an in-vehicle camera, or the like is assumed.

The imaging unit 102 generates pixel data by photoelectric conversion. As the imaging unit 102, the imaging device in the embodiments of the present technology can be used. Light from a subject is condensed and guided to a light receiving surface of the imaging unit 102 by the imaging optical system 101 disposed on an incident light side. The imaging unit 102 supplies pixel data generated by photoelectric conversion to the DSP circuit 103 in the subsequent stage.

The DSP circuit 103 executes predetermined signal processing on the pixel data from the imaging unit 102. The display unit 104 displays the pixel data. As the display unit 104, for example, a liquid crystal panel or an organic electro luminescence (EL) panel is assumed. The operation unit 105 generates an operation signal according to a user's operation. The storage unit 106 stores various types of data such as pixel data. The power supply unit 107 supplies power to the imaging unit 102, the DSP circuit 103, the display unit 104, and the like.

In the camera system 100 having the above-described configuration, the imaging device 10 according to the embodiments of the present technology, that is, the imaging device 10 capable of achieving both reduction in power consumption and improvement in image quality of a captured image can be mounted as the imaging unit 102.

In a place where there is no outlet or power supply equipment in an installation place of the camera system 100 including the imaging device 10, such as a high place, a narrow space, or the outdoors, a battery is used as a drive source. In a case where the imaging device 10 is always in the imaging state in battery driving, the second imaging mode, which is the low power consumption mode, can be set to extend the life of the battery. Then, when an event is detected, the mode is switched to the first imaging mode, which is a high image quality mode for acquiring a high resolution captured image in all pixels, to acquire a high definition captured image.

In a case where, for example, a monitoring camera is assumed as the camera system 100, the second imaging mode is set, imaging is always performed with low power consumption, and for example, when a person is detected, imaging is performed by switching to the second imaging mode, whereby a captured image with high image quality can be acquired for the person detected in the second imaging mode.

### Example of Application to Mobile Body

The technology according to the present disclosure (present technology) can be applied to various products. For example, the technology according to the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

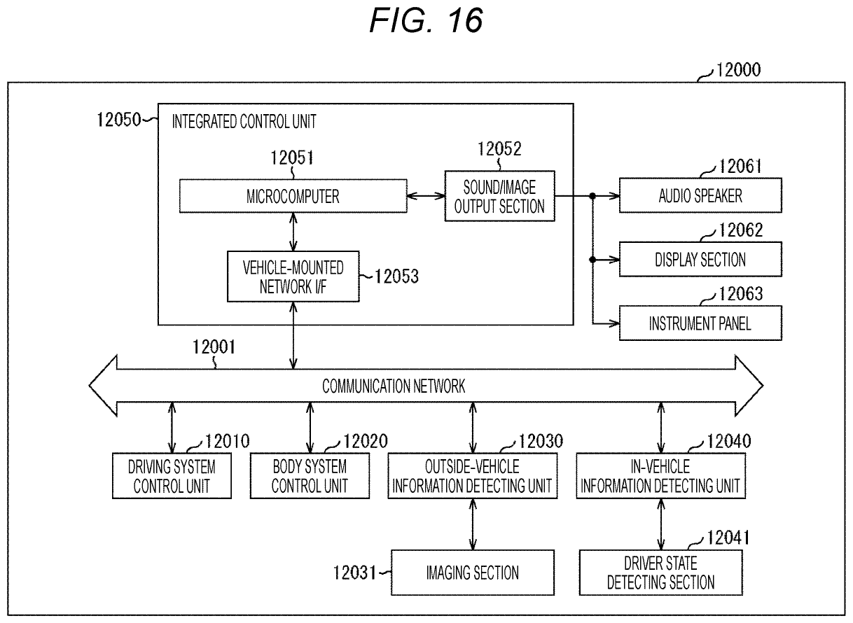

FIG. 16 is a block diagram illustrating a schematic configuration example of a vehicle control system as an example of a mobile body control system to which the technology according to the present disclosure can be applied.

The vehicle control system 12000 includes a plurality of electronic control units connected to each other via a communication network 12001. In the example illustrated in FIG. 16, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the vehicle exterior information acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 16, an audio speaker 12061, a display section 12062, and an instrument panel 12063 are exemplified as the output devices. The display section 12062 may, for example, include at least one of an on-board display and a head-up display.

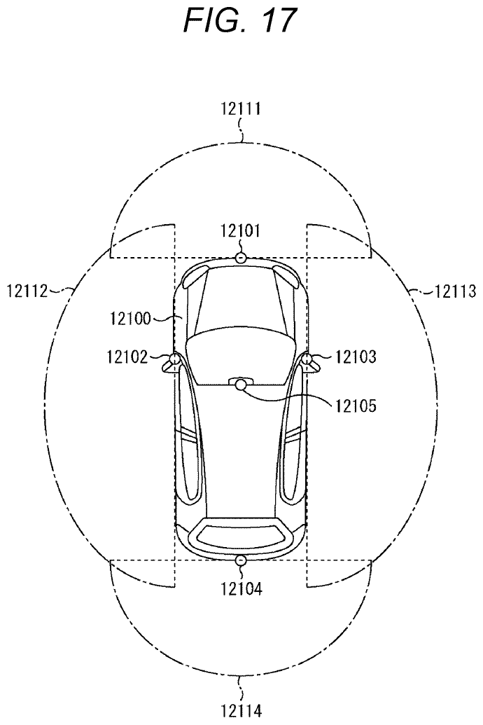

FIG. 17 is a diagram illustrating an example of an installation position of the imaging section 12031.

In FIG. 17, the imaging section 12031 includes imaging sections 12101, 12102, 12103, 12104, and 12105.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 17 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like, for example, among the configurations described above. Then, the technology according to the present disclosure, that is, the technology capable of setting the first imaging mode that is the high image quality mode and the second imaging mode that is the low power consumption mode can be applied to the imaging section 12031 and the like. As a result, the battery life can be extended by constantly performing imaging in the second imaging mode during normal operation, and a captured image with high image quality can be acquired for an obstacle or the like detected in the second imaging mode by switching to the first imaging mode when the obstacle or the like is detected.

Note that the effect described in this specification is illustrative only and is not limitative; there may also be another effect.

### Configuration that can be Taken by Present Technology

Note that the present technology may also have the following configurations.
(1) An imaging device including:
a pixel circuit including a photoelectric conversion unit and an amplification transistor having a gate electrode connected to the photoelectric conversion unit;
a first signal line connected to one electrode side of the amplification transistor;
a switching unit connected to the first signal line;
a second signal line connected to another electrode side of the amplification transistor;
a comparator having a comparison input end connected to the second signal line;
a selector connected to the first signal line and an output end of the comparator; and
a counter connected to an output end of the selector, in which
the switching unit includes
a first switch element selectively connecting the first signal line to a power supply node, and
a second switch element selectively connecting the first signal line to a current source.
(2) The imaging device according to (1), in which
the switching unit sets a first imaging mode in which image quality of a captured image is relatively high by turning on the first switch element and turning off the second switch element, and sets a second imaging mode in which power consumption is relatively low by turning off the first switch element and turning on the second switch element.
(3) The imaging device according to (2), in which
the pixel circuit includes a charge-voltage conversion unit that converts charges photoelectrically converted by the photoelectric conversion unit into a voltage, forms a source follower circuit when the first imaging mode is set, and reads the voltage of the charge-voltage conversion unit to the second signal line by the source follower circuit.
(4) The imaging device according to (2), in which
the pixel circuit includes a charge-voltage conversion unit that converts charges photoelectrically converted by the photoelectric conversion unit into a voltage, forms a grounded source amplifier when the second imaging mode is set, and reads the voltage of the charge-voltage conversion unit to the first signal line by the grounded source amplifier.
(5) The imaging device according to (4), in which
the pixel circuit reads a change in potential of the charge-voltage conversion unit as a pulse width of a digital pulse when the second imaging mode is set.
(6) The imaging device according to (2), in which
the switching unit switches to the first imaging mode and performs imaging when detecting an event at the time of imaging in the second imaging mode.
(7) The imaging device according to (2), in which
a current of the current source is set to a slope shape that linearly changes with time with a predetermined inclination when the second imaging mode is set.
(8) The imaging device according to (1), further including
a sample-and-hold circuit that samples and holds a pixel signal output from the pixel circuit when the first imaging mode is set.
(9) The imaging device according to (8), in which
the pixel circuit further includes a reset transistor that resets the charge-voltage conversion unit, and
sets a power supply voltage to be applied to the amplification transistor and a power supply voltage to be applied to the reset transistor to be different power supply voltages.
(10) An electronic device including an imaging device including:
a pixel circuit including a photoelectric conversion unit and an amplification transistor having a gate electrode connected to the photoelectric conversion unit;
a first signal line connected to one electrode side of the amplification transistor;
a switching unit connected to the first signal line;
a second signal line connected to another electrode side of the amplification transistor;
a comparator having a comparison input end connected to the second signal line;
a selector connected to the first signal line and an output end of the comparator; and
a counter connected to an output end of the selector, in which
the switching unit includes
a first switch element selectively connecting the first signal line to a power supply, and
a second switch element selectively connecting the first signal line to a current source.

### REFERENCE SIGNS LIST

10 Imaging device
11 Pixel array unit
12 Vertical scanning unit
13 Imaging mode setting unit
14 Analog-to-digital conversion unit
15 Memory unit
16 Data processing unit
17 Output unit
18 Timing control unit
19 Reference signal generation unit
20 Pixel circuit (pixel)
21 Photoelectric conversion unit (photodiode)
22 Transfer transistor
23 Charge-voltage conversion unit
24 Reset transistor
25 Amplification transistor
26 Selection transistor
31 Pixel control line
32 First signal line
33 Second signal line
34 Third signal line
35 Fourth signal line
41 First-layer semiconductor substrate
42 Second-layer semiconductor substrate
43 Connection unit
50 Sample-and-hold unit
130 Switching unit
131 Current source
140 Analog-to-digital conversion circuit
141 Load MOS
142 Comparator
143 Selector
144 Counter
501 Sample-and-hold circuit
S1 First switch element
S2 Second switch element
S3 Third switch element
S4 Fourth switch element

1. An imaging device comprising:
a pixel circuit including a photoelectric conversion unit and an amplification transistor having a gate electrode connected to the photoelectric conversion unit;
a first signal line connected to one electrode side of the amplification transistor;
a switching unit connected to the first signal line;
a second signal line connected to another electrode side of the amplification transistor;
a comparator having a comparison input end connected to the second signal line;
a selector connected to the first signal line and an output end of the comparator; and
a counter connected to an output end of the selector, wherein
the switching unit includes
a first switch element selectively connecting the first signal line to a power supply node, and
a second switch element selectively connecting the first signal line to a current source.

2. The imaging device according to claim 1, wherein
the switching unit sets a first imaging mode in which image quality of a captured image is relatively high by turning on the first switch element and turning off the second switch element, and sets a second imaging mode in which power consumption is relatively low by turning off the first switch element and turning on the second switch element.

3. The imaging device according to claim 2, wherein
the pixel circuit includes a charge-voltage conversion unit that converts charges photoelectrically converted by the photoelectric conversion unit into a voltage, forms a source follower circuit when the first imaging mode is set, and reads the voltage of the charge-voltage conversion unit to the second signal line by the source follower circuit.

4. The imaging device according to claim 2, wherein
the pixel circuit includes a charge-voltage conversion unit that converts charges photoelectrically converted by the photoelectric conversion unit into a voltage, forms a grounded source amplifier when the second imaging mode is set, and reads the voltage of the charge-voltage conversion unit to the first signal line by the grounded source amplifier.

5. The imaging device according to claim 4, wherein
the pixel circuit reads a change in potential of the charge-voltage conversion unit as a pulse width of a digital pulse when the second imaging mode is set.

6. The imaging device according to claim 2, wherein
the switching unit switches to the first imaging mode and performs imaging when detecting an event at the time of imaging in the second imaging mode.

7. The imaging device according to claim 2, wherein
a current of the current source is set to a slope shape that linearly changes with time with a predetermined inclination when the second imaging mode is set.

8. The imaging device according to claim 1, further comprising
a sample-and-hold circuit that samples and holds a pixel signal output from the pixel circuit when the first imaging mode is set.

9. The imaging device according to claim 8, wherein
the pixel circuit further includes a reset transistor that resets the charge-voltage conversion unit, and
sets a power supply voltage to be applied to the amplification transistor and a power supply voltage to be applied to the reset transistor to be different power supply voltages.

10. An electronic device comprising an imaging device including:
a pixel circuit including a photoelectric conversion unit and an amplification transistor having a gate electrode connected to the photoelectric conversion unit;
a first signal line connected to one electrode side of the amplification transistor;
a switching unit connected to the first signal line;
a second signal line connected to another electrode side of the amplification transistor;
a comparator having a comparison input end connected to the second signal line;
a selector connected to the first signal line and an output end of the comparator; and
a counter connected to an output end of the selector, in which
the switching unit includes
a first switch element selectively connecting the first signal line to a power supply node, and
a second switch element selectively connecting the first signal line to a current source.
